(19) United States
(12) Patent Application Publication
(10) Pub. No.: US 2026/0133220 A1
(43) Pub. Date: May 14, 2026

(54) Device for measuring at least one electrical quantity and associated operating diagnostic system

(71) Applicant: Schneider Electric Industries SAS, Rueil Malmaison (FR)

(72) Inventors: Thibault SEDITA, Le Versoud (FR); Vincent Geffroy, Grenoble (FR); Josè Garcia, Agey (FR); Clèment Maquin, Saint Martin d'Urlage (FR)

(21) Appl. No.: 19/381,909

(22) Filed: Nov. 6, 2025

(30) Foreign Application Priority Data
Nov. 8, 2024 (FR) FR2412239

(51) Int. Cl. G01R 1/04; G01R 19/00; G01R 31/327; G01R 31/34

(52) U.S. Cl. CPC G01R 1/0416; G01R 31/3277; G01R 19/0084; G01R 31/343

(57) ABSTRACT

The invention relates to a device for measuring (4) at least one electrical quantity of an electrical signal flowing in a contact device (2), the contact device (2) comprising, for each phase from N phases, a contact element (18) connected to an electrical phase conductor (15), the at least one electrical quantity comprising a voltage, the device for measuring (4) being configured to be installed on the front face of said contact device (2), and comprising an electronic control unit (24) comprising N flexible sheets (26), and for each phase:
a connection assembly (20) connected to one of said flexible sheets (26),
an actuating part (22) of the connection assembly (20), configured to be displaced from a free position in which the connection assembly (20) is electrically insulated from the contact device to a blocked position in which the connection assembly (20) bears against one of said contact elements (18) of the contact device.

### BACKGROUND

The present invention relates to a device for measuring at least one electrical quantity of an electrical signal flowing in a contact device of at least one electrical conductor in an electrical installation.

The invention also relates to an operating diagnostic system of an electrical installation comprising such a device for measuring.

The invention relates to the field of monitoring the operation of electrical installations and more particularly carrying out operating diagnostics of electrical installations, in particular for electrical installations in industrial fields requiring the control of motors.

Such electrical installations comprise electrical equipment such as electric motors, heating resistors or power circuits in general.

Contact devices which are configured to authorize or block a flow of an electrical signal with N phases in the item of electrical equipment are known, N being a value greater than or equal to 1. For example N=3 in the case of an electrical installation powered by a three-phase distribution network.

A contact device comprises a casing and contact connection terminals (or power contact terminals and auxiliary contact terminals), the various terminals being generally accessible on the front face of the casing.

For electrical installations, generally a plurality of contact devices are arranged in an electrical cabinet having a selected size.

In order to carry out operating diagnostics of an electrical installation, for example in order to carry out predictive maintenance of the connected electrical equipment such as electric motors, it is necessary to collect measurements of electrical quantities, in particular measurements of current consumed by the loads and voltage between electrical conductors during operating periods.

It is preferable to carry out measurements of electrical quantities in a non-invasive manner, i.e. without having to carry out modifications to cabling in an existing electrical installation.

Moreover, as the operating diagnostics require complex calculations, it is generally necessary to transmit the collected measurements of current and voltage, via a communication connection, to a remote calculation device provided with sufficient calculating power. In order to achieve this, for complex electrical installations, it is necessary to use a communication connection of sufficient output.

### SUMMARY

To this end, the subject of the invention is a device for measuring at least one electrical quantity of an electrical signal flowing in a contact device of at least one electrical conductor in an electrical installation, the contact device being configured to authorize or block a flow of an electrical current with N phases in at least one item of electrical equipment, N being a value greater than or equal to 1, connected via said at least one electrical conductor, the device for measuring comprising a casing which is configured to be installed on the front face of said contact device, the contact device comprising, for each phase, a contact element connected to the electrical conductor of said phase and accessible via the front face of the contact device, and the at least one electrical quantity comprising a voltage.

This device for measuring comprises an electronic control unit comprising N flexible sheets, and for each phase:
a connection assembly connected to one of said flexible sheets,
an actuating part of the connection assembly, the connection assembly being partially inserted into the actuating part, the actuating part being configured to be displaced in order to pass, when the device for measuring is installed on the contact device, from a free position in which the connection assembly is electrically insulated from the contact device to a blocked position in which the connection assembly bears against one of said contact elements of the contact device.

Advantageously, the installation of the proposed device for measuring does not require any electrical cabling and thus no modification in an existing electrical installation, the voltage being measured on the basis of the electrical signal received via the connection assembly and the associated flexible sheet when the actuating part is in the blocked position.

According to further advantageous aspects of the invention, the device for measuring comprises one or more of the following features, taken individually or according to all of the combinations which are technically possible.

The actuating part is configured to be translated along a given axis and rotated by a quarter turn about said axis in order to pass respectively from the free position to the blocked position and vice versa.

The casing comprises a cover, the cover comprising N guide receivers, the actuating part being inserted into one of said guide receivers and being configured to be guided in translation in said guide receiver, and wherein the actuating part comprises at least one retaining lug, said retaining lug being configured to be inserted, after translation and rotation about said axis, into a corresponding retaining housing shaped in the cover.

The connection assembly comprises a conductive element and an insulating sleeve, the insulating sleeve partially surrounding the conductive element, the conductive element also comprising a test probe which is configured to come to bear against the contact element in the blocked position.

Each flexible sheet comprises a terminal eyelet which is made of conductive material and which is arranged around the associated connection assembly so as to conduct an electrical signal between said connection assembly and the electronic control unit when the actuating part is in the blocked position.

The conductive element comprises a shoulder, the insulating sleeve being positioned so as to bear against said shoulder.

The conductive element further comprises a first spring and a second spring, said first and second springs surrounding the connection assembly and being arranged on either side of said shoulder, the first spring being arranged between the actuating part and said shoulder of the conductive element.

The second spring is made of conductive material, the second spring being configured to be in contact with the flexible sheet in the blocked position, the second spring implementing an electrical connection between the conductive element of the connection assembly and said flexible sheet.

The device for measuring is also configured to carry out measurements of current for each electrical conductor.

The device for measuring also comprises a communication interface to permit a connection to a communication network, the communication interface being configured to transmit messages comprising said measurements of at least one electrical quantity to a supervisory device connected to said communication network.

The invention further relates to an operating diagnostic system of an electrical installation, comprising a device for measuring as briefly described above, the device for measuring being installed on a contact device of said electrical installation, the diagnostic system also comprising a supervisory device, the device for measuring being configured to transmit measurements of at least one electrical quantity to said supervisory device via a communication network, the supervisory device being configured to implement at least one operating diagnostic method as a function of the at least one electrical quantity measurement received.

The invention will be understood more clearly by reading the following description, provided solely by way of non-limiting example and made with reference to the drawings, in which:

### BRIEF DESCRIPTION OF DRAWINGS

FIG. 1 is a perspective view of a contact device and a device for measuring installed on the front face of the contact device;

FIG. 2 is a sectional view of a device for measuring and a contact device in two separate positions of a connection assembly of the device for measuring;

FIG. 3 shows a connection assembly and an actuating part according to an embodiment;

FIG. 4 shows a first cover of a device for measuring and a detail of an actuating part;

FIG. 5 shows a detail of FIG. 2 in the blocked position;

FIG. 6 shows a second cover of a device for measuring;

FIG. 7 is a block diagram of the principal function blocks of a diagnostic system comprising a device for measuring.

### DETAILED DESCRIPTION

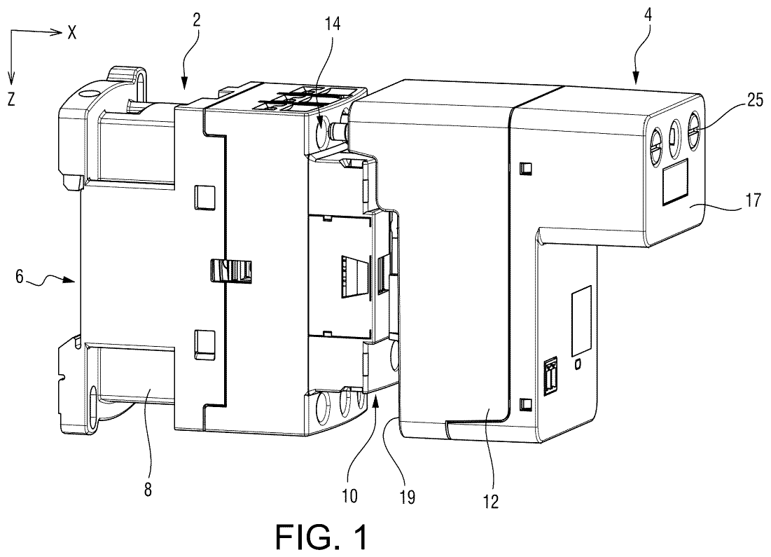

FIG. 1 illustrates a contact device 2 and a device for measuring 4 installed on the front face of the contact device.

The contact device 2 is designed to be installed in an electrical installation, not shown.

In various applications, the contact device 2 is installed in an electrical board or in an electrical cabinet by fixing parts of the rear part 6 of its casing 8. The front face of the casing 8, also called front face 10 of the contact device 2, is accessible by an operator.

In the following description, the term “connected” relates to an electrical connection and the term “conductor” is understood to mean an electrical conductor.

The device for measuring 4 comprises a casing 12, the casing 12 of the device for measuring being configured to be fixed mechanically, for example by interlocking, to the contact device 2, and more particularly to the front face 10 of the casing 8 of the contact device 2.

The casing 12 comprises a first cover 17, or front cover, and a second cover 19, or rear cover, the rear cover being at least partially in contact with the front face 10 of the casing 8 when the device for measuring 4 is installed on the contact device 2.

The contact device 2 comprises connection terminals 14 for electrical conductors (not shown in FIG. 1).

In the illustrated example, the contact device 2 comprises three connection terminals 14 respectively corresponding to an electrical installation with three-phase current, each connection terminal being associated with an electrical phase conductor.

More generally, the contact device 2 is configured to authorize or to block a flow of electrical current with N phases, and comprises a number N of connection terminals, N being a value greater than or equal to 1, preferably greater than or equal to 2.

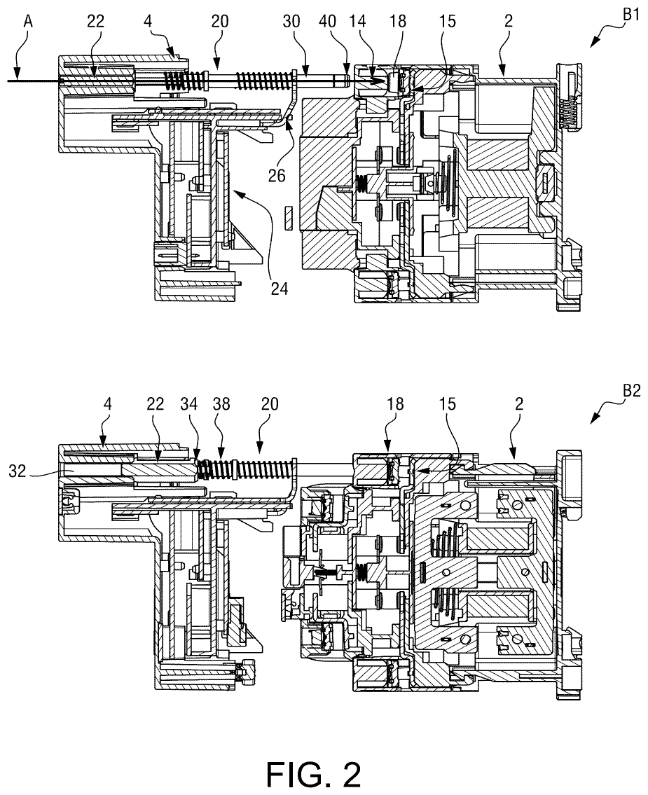

Each respective connection terminal 14 comprises an electrical contact element 18 (also called a contact element 18) with the electrical conductor 15, as illustrated in FIG. 2.

For example, the electrical contact element 18 is a conductive screw head of a screw-nut connection assembly. When an electrical conductor 15 is connected via a connection terminal 14, the electrical contact element 18 is electrically connected to the electrical conductor 15.

The device for measuring 4 is configured to measure electrical quantities of the electrical signal flowing in the electrical conductor 15, via an electrical connection mechanism on the front face 35, to the electrical contact element 18 of the corresponding connection terminal 14.

In the remainder of the description, the elements which contribute to the implementation of this electrical connection mechanism on the front face 35 for an electrical phase conductor 15 are described with reference to FIGS. 2 to 6, it being understood that the device for measuring 4 comprises as many electrical connection mechanisms on the front face as terminals 14.

In two inserts referenced B1 and B2 of sectional views of the device for measuring 4 in two positions, FIG. 2 respectively shows a so-called free position (insert B1) and a so-called blocked position (insert B2) described in detail below.

It is noteworthy that the contact device 2 and the device for measuring 4 are shown in an exploded sectional view in FIG. 2 to facilitate the understanding of the various elements.

The device for measuring 4 comprises, for each phase, a connection assembly 20 arranged in an actuating part 22. The connection assembly 20 and the actuating part 22 cooperate to implement the electrical connection mechanism on the front face 35.

The device for measuring 4 also comprises an electronic control unit 24 comprising N flexible sheets 26 extending outside the electronic control unit, each flexible sheet 26 having a conductive region.

The connection assembly 20 is partially inserted into the actuating part 22, so that the displacement of the actuating part 22 causes the displacement of the connection assembly 20.

The actuating part 22 is inserted into a guide receiver 32 of the casing 12 of the device for measuring, in practice the guide receiver 32 (or guide housing) being formed in the first cover 17 of the casing 12 of the device for measuring.

The actuating part 22 is configured to be translated along an axis A and rotated by a quarter turn about said axis.

In one embodiment, the actuating part 22 is of substantially cylindrical shape and the guide receiver 32 has a similar shape, having a diameter tailored to the diameter of the actuating part 22.

The axis A is defined relative to the receiver 32, for example the receiver 32 is substantially cylindrical and the axis A is the central axis of the cylinder forming the receiver 32.

The actuating part 22 comprises an end piece 25 which is provided with an indentation, accessible on the front face of the casing 12 of the device for measuring, and which is capable of being pushed and rotated by means of an external device, for example by means of a screwdriver (not shown in the figures).

The arrangement of the receiver 32 and the actuating part 22 in this receiver is such that, when the device for measuring 4 is installed on the front face of the contact device 2, the housing 32 is aligned with the connection terminal 14 as shown in FIG. 2.

The actuating part 22 is configured to be displaced from the free position (insert B1) to the blocked position (insert B2) and vice versa. In the free position, there is no contact with the contact element 18.

Starting from the free position (insert B1 of FIG. 2), when the actuating part 22 is translated in the direction of the contact device 2 (direction indicated by the arrow on the axis A) the connection assembly 20 comes to bear against the electrical contact element 18 of the connection terminal 14 in the blocked position, as shown in the insert B2. Thus, in the blocked position, the connection assembly 20 is in physical contact and forms an electrical connection with the electrical contact element 18 of the connection terminal 14.

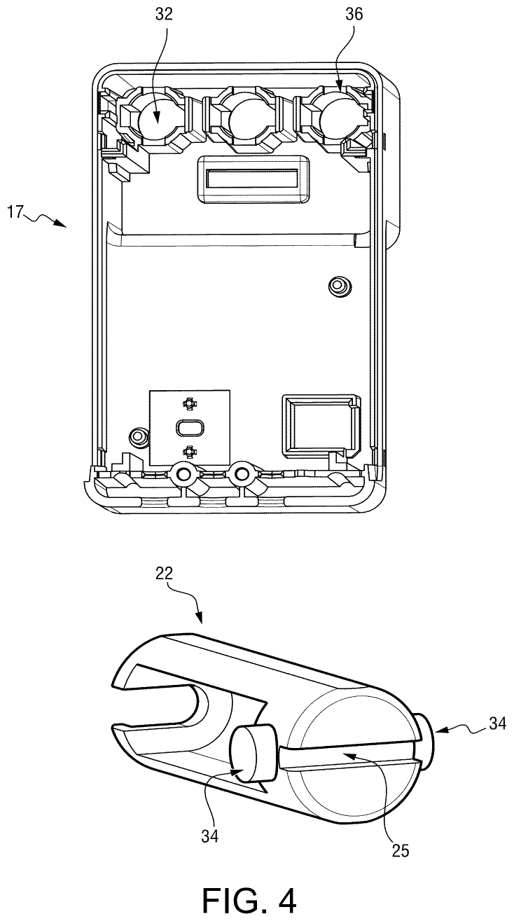

In one embodiment and as illustrated in further detail in FIG. 4, in order to hold the connection assembly 20 bearing against the electrical contact element 18 in the blocked position, the actuating part 22 comprises retaining lugs 34, for example two diametrically opposing retaining lugs, configured to be inserted into retaining housings 36 of the first cover 17 of the casing 12 of the device for measuring 4, after the translation into the guide receiver 32 in the direction of the contact device 2 and the rotation of the actuating part 22 by a quarter turn about the axis A.

Moreover, the connection assembly 20 is guided toward the connection terminal 14 through rear housings 31 which are formed in the second cover (or rear cover) 19. The rear housing 31 is configured to be aligned with the connection terminals 14 when the device for measuring 4 is installed on the contact device 2.

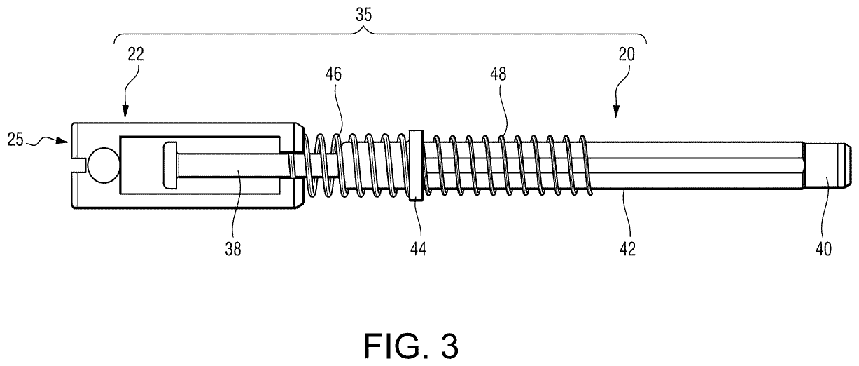

As illustrated in more detail in FIG. 3, the connection assembly 20 comprises a conductive element 38, e.g. a metallic element, comprising a test probe 40 and a sleeve 42 made of insulating material, for example made of plastics.

The conductive element 38 forms a metallic core of the connection assembly 20 and extends over the entire connection assembly 20. The test probe 40 is the end of the connection assembly 20, located opposite the actuating part 22. The test probe 40 is the part of the connection assembly 20 which comes to bear against the contact element 18 in the blocked position and exerts a pressing force on the contact element 18 in this blocked position.

The test probe 40 preferably has a disk shape, having a diameter close to the diameter of the screw head forming the contact element 18.

As illustrated in FIG. 3, in one embodiment the sleeve 42 partially covers the conductive element 38.

Moreover, the conductive element 38 comprises a shoulder 44, as visible more particularly in FIG. 3.

The sleeve 42 in the embodiment of FIG. 3 bears against the shoulder 44.

The connection mechanism on the front face also comprises two springs, respectively a first spring 46 and a second spring 48 which are arranged on either side of the shoulder 44 of the conductive element 38.

The first spring 46, also called the retaining spring, is arranged between the actuating part 22 and the shoulder 44 of the conductive element 38 of the connection assembly. This first spring 46 has the function of maintaining a contact bearing force of the test probe 40 in the blocked position.

Preferably, the first spring 46 is selected such that the contact pressure force exerted by the connection assembly 20 on the contact element 18 is at least equal to 1 Newton.

The second spring 48 has a return spring function for the connection assembly when the device for measuring 4 is dismantled.

Moreover, the second spring 48 is made of conductive material (metallic spring) and also has an electrical contact function, permitting the flow of an electrical signal between the contact element 18 and the electronic control unit 24 via the flexible sheet 26 which is electrically connected to one end of the spring 48 in the blocked position.

Preferably, the force of the first spring 46 in the blocked position is greater by at least 1 Newton than the force of the second spring 48.

Preferably, the first spring 46 and the second spring 48 are treated so as to be conductive on the surface, for example by tin-plating or nickel-plating.

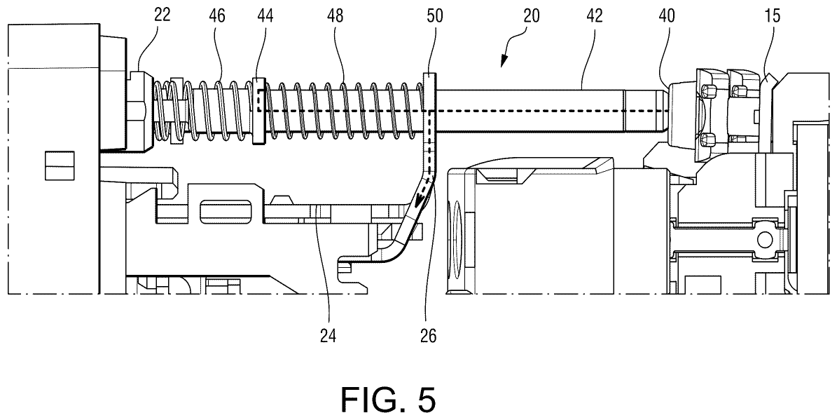

In one embodiment, the flexible sheet 26 comprises an terminal eyelet 50 made of conductive material and the connection assembly 20 passes through the terminal eyelet 50 as illustrated, in particular, in FIG. 5.

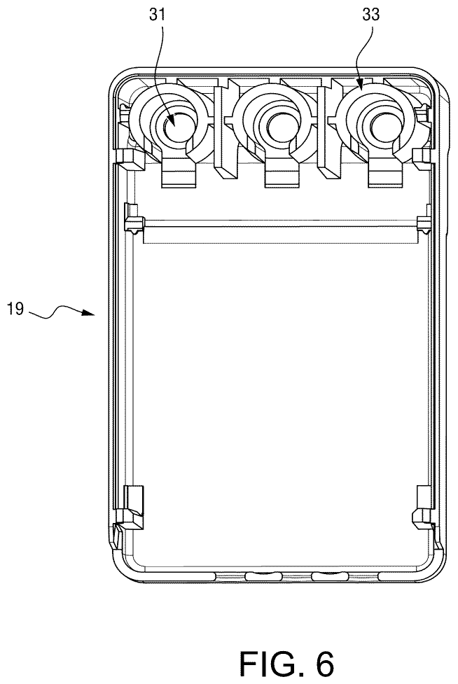

The second spring 48 is arranged between the shoulder 44 and the terminal eyelet 50. In the blocked position, the terminal eyelet 50 comes into abutment against a stop element 33 which belongs to the second cover 19, in one embodiment illustrated in FIG. 6. In the blocked position, a first end of the second spring 48 bears against the shoulder 44 and a second end of the second spring 48 bears against the terminal eyelet 50 which is in abutment against the stop element 33. Advantageously, the stop element 33 makes it possible to ensure the mechanical contact and the electrical connection between the terminal eyelet 50 and the second spring 48.

The second spring 48 conducts an electrical signal between the shoulder 44 and the terminal eyelet 50, which makes it possible to route the electrical signal via the flexible sheet 26 to the electronic control unit 24.

Thus the actuating part 22, the connection assembly 20, the flexible sheet 26 and the electronic control unit 24, in the arrangement described above, cooperate to implement a measurement of voltage in the region of the electrical contact element 18 of the contact device 2.

Moreover, in one embodiment, the electronic control unit 24 is also configured to carry out measurements of electrical current consumed by a load (for example an item of electrical equipment) connected downstream of the contact 2.

In one embodiment, the measurements of electrical current consumed by the load (not shown) are implemented by current sensors arranged on phase cables connected to the terminals downstream of the contact 2. Each respective current sensor is connected by a conductive wire to the electronic control unit 4.

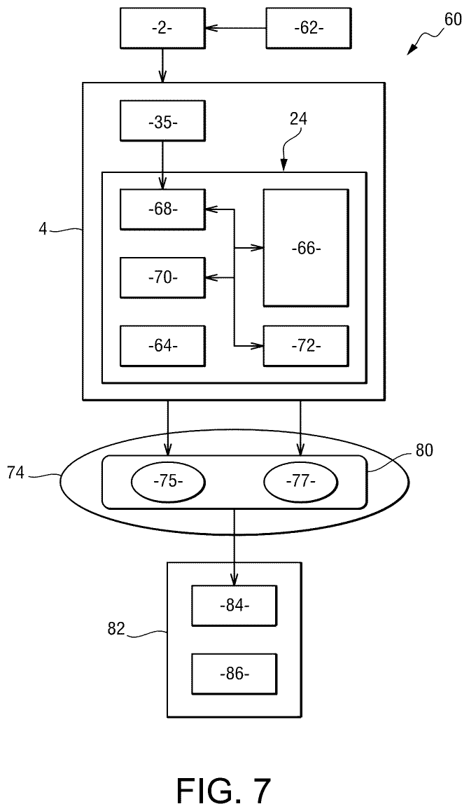

FIG. 7 is a block diagram of the principal function blocks of an operating diagnostic system 60 of an electrical installation comprising at least one item of electrical equipment 62 connected via a contact device 2 to an electrical source, not shown.

The diagnostic system 60 comprises a device for measuring 4 as described above, comprising a connection mechanism on the front face 35, as described, and an electronic control unit 24, the connection mechanism 35 making it possible to route the electrical signal from the contact device 2 to the electronic control unit 24 for each phase conductor, as described above.

The electronic control unit 24 is powered by a power supply unit 64 and comprises a processor or microcontroller 66 implemented, for example, in the form of electronic circuit designed to manipulate and/or transform data, represented by electronic or physical quantities in registers of the control unit and/or memories, into other similar data corresponding to physical data in the register memories or other types of display devices, transmission devices or storage devices.

The electronic control unit 24 also comprises a module 68 for dividing and formatting voltage signals, a module 70 for receiving current and voltage signals and formatting current signals from respective current sensors.

In the embodiments, the module 66 is implemented in the form of a programmable software component, such as a FPGA (Field Programmable Gate Array) or even an integrated circuit such as an ASIC (Application Specific Integrated Circuit). The module 68 is implemented, for example, by a resistance bridge. The module 70 is, for example, an analogue-digital converter (CAN).

The electronic control unit 24 also comprises a communication interface 72 configured to permit a connection to a communication network 74, for example a wired 10BASE-T1S ethernet network.

The electronic control unit 24 is thus configured to provide measurements of current 75 and measurements of voltage 77 which are formatted into communication messages 80 and transmitted via the communication network 74 to a supervisory device 82.

The supervisory device 82 is also provided with a communication interface 84 capable of communicating with the communication interface 72 of the device for measuring.

The supervisory device 82 also comprises a controller 86 configured to carry out operating diagnostic calculations as a function of the measurements of electrical quantities received, i.e. the measurements of voltage and the measurements of current received, according to known operating diagnostic procedures.

According to variants, the device for measuring is configured to provide only voltage measurements 77, and the supervisory device 82 is configured to carry out operating diagnostic calculations from the voltage measurements received.

Thus it is possible from such operating diagnostics to highlight situations which deviate from a nominal operation and as a result to provide predictive maintenance measures in order to avoid the occurrence of a malfunction of the item of electrical equipment 62.

Advantageously, the device for measuring 4 is provided with a communication interface making it possible to carry out communications with sufficient output to transmit measurements of voltage, and optionally measurements of current, enabling operating diagnostic calculations to be carried out.

Advantageously, the device for measuring 4 can be installed on the front face of a contact device 2 without having to carry out any modification to electrical cabling. Thus the installation of such a device is simple and non-invasive, and it is compatible with taking measurements on existing electrical installations.

1. A device for measuring at least one electrical quantity of an electrical signal flowing in a contact device of at least one electrical conductor in an electrical installation, the contact device being configured to authorize or block a flow of an electrical current with N phases in at least one item of electrical equipment, N being a value greater than or equal to 1, connected via said at least one electrical conductor, the device for measuring comprising a casing which is configured to be installed on the front face of said contact device, the contact device comprising, for each phase, a contact element connected to the electrical conductor of said phase and accessible via the front face of the contact device, the at least one electrical quantity comprising a voltage, the device for measuring being characterized in that it comprises an electronic control unit comprising N flexible sheets, and for each phase:
a connection assembly connected to one of said flexible sheets,
an actuating part of the connection assembly, the connection assembly being partially inserted into the actuating part, the actuating part being configured to be displaced in order to pass, when the device for measuring is installed on the contact device, from a free position in which the connection assembly is electrically insulated from the contact device to a blocked position in which the connection assembly bears against one of said contact elements of the contact device.

2. The device for measuring according to claim 1, wherein said actuating part is configured to be translated along a given axis and rotated by a quarter turn about said axis in order to pass respectively from the free position to the blocked position and vice versa.

3. The device for measuring according to claim 2, wherein the casing comprises a cover, the cover comprising N guide receivers, the actuating part being inserted into one of said guide receivers and being configured to be guided in translation in said guide receiver and wherein the actuating part comprises at least one retaining lug, said retaining lug being configured to be inserted, after translation and rotation about said axis, into a corresponding retaining housing shaped in the cover.

4. The device for measuring according to claim 1, wherein the connection assembly comprises a conductive element and an insulating sleeve, the insulating sleeve partially surrounding the conductive element, the conductive element also comprising a test probe which is configured to come to bear against the contact element in the blocked position.

5. The device for measuring according to claim 4, wherein each flexible sheet comprises a terminal eyelet which is made of conductive material and which is arranged around the associated connection assembly so as to conduct an electrical signal between said connection assembly and the electronic control unit when the actuating part is in the blocked position.

6. The device for measuring according to claim 4, wherein the conductive element comprises a shoulder, the insulating sleeve being positioned so as to bear against said shoulder.

7. The device for measuring according to claim 6 also comprising a first spring and a second spring, said first spring and second spring surrounding the connection assembly and being arranged on either side of said shoulder, the first spring being arranged between the actuating part and said shoulder of the conductive element.

8. The device for measuring according to claim 7, wherein the second spring is made of conductive material, the second spring being configured to be in contact with the flexible sheet in the blocked position, the second spring implementing an electrical connection between the conductive element of the connection assembly and said flexible sheet.

9. The device for measuring according to claim 1, also configured to carry out measurements of current for each electrical conductor.

10. The device for measuring according to claim 1, also comprising a communication interface to permit a connection to a communication network, the communication interface being configured to transmit messages comprising said measurements of at least one electrical quantity to a supervisory device connected to said communication network.

11. An operating diagnostic system of an electrical installation, comprising a device for measuring according to claim 1, the device for measuring being installed on a contact device of said electrical installation, the diagnostic system also comprising a supervisory device, the device for measuring being configured to transmit measurements of at least one electrical quantity to said supervisory device via a communication network, the supervisory device being configured to implement at least one operating diagnostic method as a function of the at least one electrical quantity measurement received.
